(19) United States
(12) Patent Application Publication
(10) Pub. No.: US 2024/0079449 A1
(43) Pub. Date: Mar. 7, 2024

(54) SEMICONDUCTOR STRUCTURE AND METHOD FOR MANUFACTURING THE SAME

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/454,746

(22) Filed: Aug. 23, 2023

(30) Foreign Application Priority Data
Sep. 5, 2022 (CN) 202211080657.4

(51) Int. Cl. H01L 29/06; H01L 21/308; H01L 29/267; H01L 29/66; H01L 29/812

(52) U.S. Cl. CPC H01L 29/0684; H01L 21/308; H01L 29/267; H01L 29/66856; H01L 29/8122

(57) ABSTRACT

A semiconductor structure includes: a first semiconductor layer, including a first surfaces and a second surfaces opposite to the first surface; a second semiconductor layer, disposed on the first semiconductor layer, where a conductive type of the second semiconductor layer is the same as that of the first semiconductor layer, and a doping concentration of the second semiconductor layer is less than that of the first semiconductor layer; grooves, formed in the second semiconductor layer; and a third semiconductor layer, where a conductive type of the third semiconductor layer is different from that of the second semiconductor layer, a material of the third semiconductor layer is different from that of the second semiconductor layer, and at least a portion of the third semiconductor layer is disposed in the grooves.

### CROSS REFERENCE TO RELATED APPLICATIONS

This application claims priority to Chinese Patent Application No. 202211080657.4 filed on Sep. 5, 2022, the entire contents of which is incorporated herein by reference.

### TECHNICAL FIELD

The disclosure relates to the field of semiconductor technology, and in particular to a semiconductor structure and a method for manufacturing a semiconductor structure.

### BACKGROUND

With the development of microelectronics technology, the performance of traditional first-generation Si semiconductors and second-generation GaAs semiconductor power devices has approached the theoretical limits determined by their materials. In order to further reduce an area of a chip, silicon carbide (SiC), and gallium nitride (GaN) as a representative of wide bandwidth semiconductor materials have greatly expanded the energy processing ability of power devices by virtue of their high critical breakdown electric field, high thermal conductivity, high saturation drift speed of hot carriers, and strong radiation resistance, to meet the requirements of the next generation of power electronic equipment for higher power, smaller volume, and worse working conditions of power devices, and are gradually applied in various fields of power electronic systems.

Vertical conductive semiconductors have a high electric field at high frequencies, which intensifies at the groove corners, and have poor resistance to harsh electrostatic effects and high voltage spikes in the circuit. In practice, high-frequency peak voltage surges during switching can sometimes lead to breakdown failure in the channel region of the device. In addition, Schottky barrier diodes have a problem of high reverse leakage current, which reduces device reliability.

### SUMMARY

the present disclosure aims to provide a semiconductor structure and a method for manufacturing a semiconductor structure. The groove structure formed by the secondary epitaxial semiconductor layer after etching can increase the breakdown voltage of the semiconductor structure composition device, reduce the manufacture time, and automatically adjust the device conduction resistance, thereby the current processing ability of the power semiconductor is improved.

According to a first aspect of the present disclosure, there is provided a semiconductor structure, including: a first semiconductor layer, including a first surfaces and a second surfaces opposite to the first surface; a second semiconductor layer, disposed on the first semiconductor layer, where a conductive type of the second semiconductor layer is the same as that of the first semiconductor layer, and a doping concentration of the second semiconductor layer is less than that of the first semiconductor layer; grooves, formed in the second semiconductor layer; and a third semiconductor layer, where a conductive type of the third semiconductor layer is different from that of the second semiconductor layer, a material of the third semiconductor layer is different from that of the second semiconductor layer, and at least a portion of the third semiconductor layer is disposed in the grooves.

In an embodiment, a width of the third semiconductor layer periodically varies, gradually increases, gradually decreases, first increases and then decreases or first decreases and then increases along an epitaxial direction.

In an embodiment, the conductive type of the first semiconductor layer is an N-type, and the conductive type of the third semiconductor layer is a P-type; or the conductive type of the first semiconductor layer is a P-type, and the conductive type of the third semiconductor layer is a N-type.

In an embodiment, the semiconductor structure further includes a buffer layer, which is provided between the first semiconductor layer and the second semiconductor layer.

In an embodiment, a material of the first semiconductor layer and the material of the second semiconductor layer include at least one of Si, SiC or GaN, and the material of the third semiconductor layer includes AlGaN; or a material of the first semiconductor layer and the material of the second semiconductor layer include at least one of Si, SiC or GaN, and the material of the third semiconductor layer includes SiC.

In an embodiment, when the material of the second semiconductor layer is GaN and the material of the third semiconductor layer is AlGaN, a change curve of an Al component transitions continuously at a contact interface between the third semiconductor layer and the second semiconductor layer; when the material of the second semiconductor layer is SiC and the material of the third semiconductor layer is AlGaN, the change curve of the Al component has a jump at the contact interface between the third semiconductor layer and the second semiconductor layer.

In an embodiment, in the epitaxial direction, a change curve of an Al component of the third semiconductor layer includes one or more combinations of a periodic change, an incremental change and a decremental change.

In an embodiment, the semiconductor structure further includes a fourth semiconductor structure formed on the second semiconductor layer, where a conductive type of the fourth semiconductor structure is the same as that of the second semiconductor layer, a doping concentration of the fourth semiconductor structure is greater than that of the second semiconductor layer, and the grooves penetrate the fourth semiconductor structure and extend into the second semiconductor layer.

In an embodiment, the third semiconductor layer extends outside the grooves and heals into a flat surface, and the third semiconductor layer outside the grooves is ion-implanted to form the fourth semiconductor structure.

In an embodiment, the semiconductor structure further includes a source electrode, a gate electrode, and a drain electrode, where the source electrode is disposed on the second semiconductor layer, the gate electrode is disposed on a top surface of the third semiconductor layer, and the drain electrode is disposed on the second surface of the first semiconductor layer.

In an embodiment, the semiconductor structure further includes: a first electrode, disposed on a top surface of the third semiconductor layer; and a second electrode, disposed on the second surface of the first semiconductor layer.

According to a second aspect of the present disclosure, there is provided a method for manufacturing a semiconductor structure, including: providing a first semiconductor layer; forming a second semiconductor layer on the first semiconductor layer, where a conductive type of the second semiconductor layer is the same as that of the first semiconductor layer, and a doping concentration of the second semiconductor layer is less than that of the first semiconductor layer; forming a mask layer on a surface of the second semiconductor layer away from the first semiconductor layer, where the mask layer is provided with windows exposing the second semiconductor layer; etching the second semiconductor layer by using the mask layer as a mask to form grooves in the second semiconductor layer, where the grooves correspond to the windows; and epitaxially growing a third semiconductor layer, where a conductive type of the third semiconductor layer is different from that of the second semiconductor layer, a material of the third semiconductor layer is different from that of the second semiconductor layer, and at least a portion of the third semiconductor layer is disposed in the grooves.

In an embodiment, a width of the third semiconductor layer periodically varies, gradually increases, gradually decreases, first increases and then decreases or first decreases and then increases along an epitaxial direction.

In an embodiment, a material of the first semiconductor layer and the material of the second semiconductor layer include at least one of Si, SiC or GaN, and the material of the third semiconductor layer includes AlGaN; or a material of the first semiconductor layer and the material of the second semiconductor layer include at least one of Si, SiC or GaN, and the material of the third semiconductor layer includes SiC.

In an embodiment, when the material of the second semiconductor layer is GaN and the material of the third semiconductor layer is AlGaN, a change curve of an Al component transitions continuously at a contact interface between the third semiconductor layer and the second semiconductor layer; when the material of the second semiconductor layer is SiC and the material of the third semiconductor layer is AlGaN, the change curve of the Al component has a jump at the contact interface between the third semiconductor layer and the second semiconductor layer.

In an embodiment, in the epitaxial direction, a change curve of an Al component of the third semiconductor layer includes one or more combinations of a periodic change, an incremental change and a decremental change.

In an embodiment, the method further includes: selectively growing a fourth semiconductor structure on the second semiconductor layer which is etched; or before forming the mask layer: forming a fourth semiconductor structure on the second semiconductor layer, where the mask layer is formed on a surface of the fourth semiconductor structure away from the second semiconductor layer, and the grooves penetrate the fourth semiconductor structure and extend into the second semiconductor layer; or growing the third semiconductor layer to extend outside the recess and heal into a flat surface, where the third semiconductor layer outside the grooves is ion-implanted to form the fourth semiconductor structure; where a conductive type of the fourth semiconductor structure is the same as that of the second semiconductor layer, a doping concentration of the fourth semiconductor structure is greater than that of the second semiconductor layer.

In an embodiment, the method further includes: removing the mask layer; forming a first electrode, where the first electrode is in contact with the third semiconductor layer and in contact with the second semiconductor layer disposed between two adjacent grooves; and forming a second electrode on a side of the first semiconductor layer away from the second semiconductor layer.

In an embodiment, a protrusion is formed between two adjacent grooves, and the method further includes: removing the mask layer; forming a gate electrode on a side of the third semiconductor layer away from the first semiconductor layer; forming a source electrode on a top surface of the protrusion; and forming a drain electrode on a side of the first semiconductor layer away from the second semiconductor layer.

In an embodiment, forming the second semiconductor layer on the first semiconductor layer includes: forming a buffer layer covering the first semiconductor layer, and forming the second semiconductor layer on a side of the buffer layer away from the first semiconductor layer.

### BRIEF DESCRIPTION OF DRAWINGS

FIG. 1 is a schematic diagram illustrating a structure after forming a mask layer according to an embodiment I of the present disclosure.

FIG. 2 is a schematic diagram illustrating a structure after forming grooves according to the embodiment I of the present disclosure.

FIG. 3 is a schematic diagram illustrating a structure after forming a third semiconductor layer according to the embodiment I of the present disclosure.

FIG. 4 is a plan view illustrating the semiconductor structure manufactured according to the embodiment I of the present disclosure.

FIG. 5 is a schematic diagram illustrating a semiconductor structure manufactured according to an embodiment II of the present disclosure.

FIG. 6 is a schematic diagram illustrating a semiconductor structure manufactured according to an embodiment III of the present disclosure.

FIG. 7 is a schematic diagram illustrating a semiconductor structure manufactured according to an embodiment IV of the present disclosure.

FIG. 8 is a schematic diagram illustrating a structure after forming a mask layer according to the embodiment IV of the present disclosure.

FIG. 9 is a schematic diagram illustrating a structure after forming grooves according to the embodiment IV of the present disclosure.

FIG. 10 is a schematic diagram illustrating a semiconductor structure manufactured according to an embodiment V of the present disclosure.

FIGS. 11 to 13 are schematic diagrams illustrating a semiconductor structure manufactured according to an embodiment VI of the present disclosure.

FIGS. 14 to 16 are graphs illustrating changes of an Al component in a third semiconductor layer.

FIG. 17 is a schematic diagram illustrating a structure after forming a third semiconductor layer according to an embodiment VII of the present disclosure.

FIG. 18 is a schematic diagram illustrating a structure after forming a fourth semiconductor layer according to the embodiment VII of the present disclosure.

List of reference numerals: a first semiconductor layer 1; a second semiconductor layer 2; groove 201; protrusion 202; mask layer 3; window 301; third semiconductor layer 4; first electrode 5; second electrode 6; source electrode 7; gate electrode 8; drain electrode 9; fourth semiconductor structure 10; buffer layer 11.

### DETAILED DESCRIPTION

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

### Embodiment I

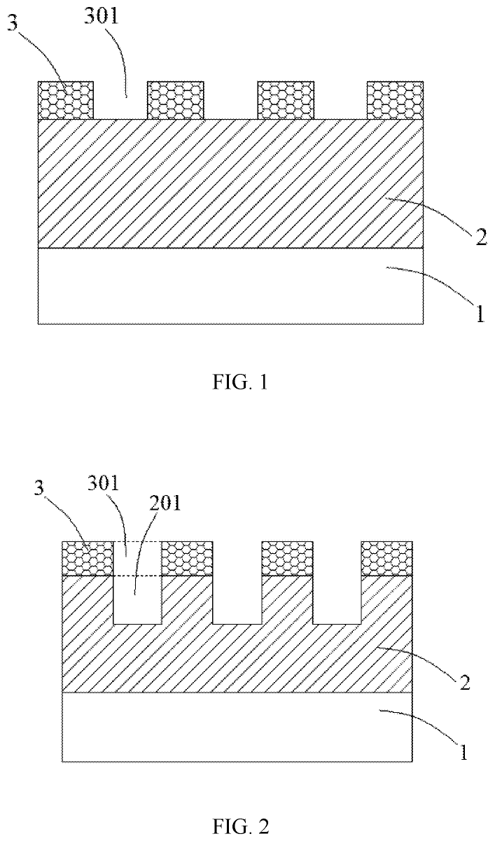

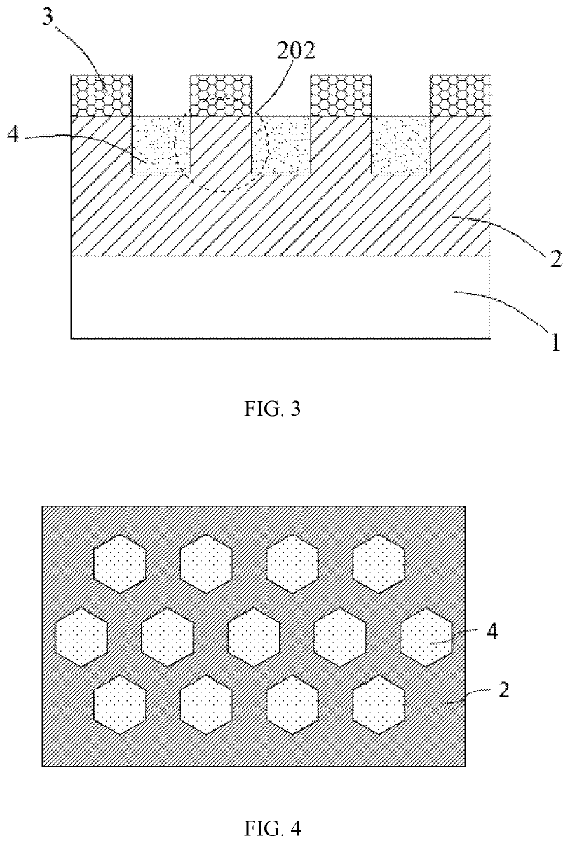

The embodiment I of the present disclosure provides a semiconductor structure and a method for manufacturing the semiconductor structure. FIG. 1 is a schematic diagram illustrating a structure after forming a mask layer according to an embodiment I of the present disclosure. FIG. 2 is a schematic diagram illustrating a structure after forming grooves according to the embodiment I of the present disclosure. FIG. 3 is a schematic diagram illustrating a structure after forming a third semiconductor layer according to the embodiment I of the present disclosure. The method for manufacturing the semiconductor structure may include steps S100 to S140.

At step S100, a first semiconductor layer 1 is provided.

At step S110, a second semiconductor layer 2 is formed on the first semiconductor layer 1. A conductive type of the second semiconductor layer 2 is the same as that of the first semiconductor layer 1, and a doping concentration of the second semiconductor layer 2 is less than that of the first semiconductor layer 1.

At step S120, a mask layer 3 is formed on a surface of the second semiconductor layer 2 away from the first semiconductor layer 1. The mask layer 3 is provided with windows 301 exposing the second semiconductor layer 2.

At step S130, the second semiconductor layer 2 is etched by using the mask layer 3 as a mask, to form grooves 201 in the second semiconductor layer 2. The grooves 201 correspond to the windows 301.

At step S140, a third semiconductor layer 4 is epitaxially grown. A conductive type of the third semiconductor layer 4 is different from that of the second semiconductor layer 2, a material of the third semiconductor layer 4 is different from that of the second semiconductor layer 2, and at least a portion of the third semiconductor layer 4 is disposed in the grooves 201.

In this embodiment of the present disclosure, the third semiconductor layer 4 in the grooves 201 is manufactured by epitaxial growth. Since the mask layer 3 covers a region of the second semiconductor layer 2 located outside of the grooves 201, it is difficult for the third semiconductor layer 4 to be grown in the region other than the grooves 201, and it is avoided to remove the third semiconductor layer 4 outside of the grooves 201 by subsequent grinding process (for example, chemical mechanical polishing (CMP) process), thereby the manufacturing efficiency is improved and the manufacture time is reduced.

Each step of the method for manufacturing the semiconductor structure in this embodiment of the present disclosure is described in detail below.

In step S100, the first semiconductor layer 1 is provided.

The material of the first semiconductor layer 1 may be a III-V group compound. Specifically, the material of the first semiconductor layer 1 may be at least one of GaN, aluminum gallium nitride (AlGaN), indium gallium nitride (InGaN), or aluminum indium gallium nitride (AlInGaN). In other embodiments of the present disclosure, the material of the first semiconductor layer 1 may also be at least one of Si, or SiC. The first semiconductor layer 1 may be doped with N-type ions, such that the first semiconductor layer 1 is an N-type semiconductor layer. The N-type ions may be at least one of Si ions, Ge ions, Sn ions, Se ions, or Te ions. The concentration of the N-type ions doped in the first semiconductor layer 1 is larger, such that the first semiconductor layer 1 is an N-type heavily doped layer, and the doping concentration of the doping ions in the first semiconductor layer 1 may be 10¹⁸/cm³ or more. The first semiconductor layer 1 may be a single-layer structure or a stacked-layer structure, and the material of each layer may be GaN, AlGaN, or AlInGaN, or other semiconductor material including Ga atoms and N atoms, or a mixture of at least two of the above materials. In some embodiments, the first semiconductor layer 1 may also be a P-type semiconductor layer.

In step S110, the second semiconductor layer 2 is formed on the first semiconductor layer 1. A conductive type of the second semiconductor layer 2 is the same as that of the first semiconductor layer 1, and a doping concentration of the second semiconductor layer 2 is less than that of the first semiconductor layer 1.

The material of this second semiconductor layer 2 may be a III-V group compound. Specifically, the material of the second semiconductor layer 2 may be at least one of GaN, AlGaN, InGaN, AlInGaN. The second semiconductor layer 2 has the same conductive type as the first semiconductor layer 1. When the first semiconductor layer 1 is an N-type semiconductor layer, the second semiconductor layer 2 is also an N-type semiconductor layer. When the first semiconductor layer 1 is a P-type semiconductor layer, the second semiconductor layer 2 is also a P-type semiconductor layer. The doping concentration of the second semiconductor layer 2 is less than the doping concentration of the first semiconductor layer 1. When the first semiconductor layer 1 is an N-type heavily doped layer, for example, the second semiconductor layer 2 may be an N-type lightly doped layer, and the doping concentration of doping ions in the second semiconductor layer 2 may be 10¹⁸/cm³ or less. The second semiconductor layer 2 may be a single-layer structure or a stacked-layer structure, and the material of each layer may be GaN, AlGaN, or AlInGaN, or other semiconductor material including Ga atoms and N atoms, or a mixture of at least two of the above materials. In other embodiments of the present disclosure, the material of the second semiconductor layer 2 may also be at least one of Si, or SiC. The second semiconductor layer 2 may be formed by epitaxial growth, but embodiments of the present disclosure are not specifically limited thereto.

In step S120, a mask layer 3 is formed on the surface of the second semiconductor layer 2 away from the first semiconductor layer 1, and the mask layer 3 is provided with a plurality of windows 301 exposing the second semiconductor layer 2.

The mask layer 3 may be manufactured by a photolithography process. The material of the mask layer 3 may be an insulating material, such as SiO₂, etc.

In step S130, the second semiconductor layer 2 is etched by using the mask layer 3 as a mask to form a plurality of grooves 201 on the second semiconductor layer 2. The plurality of grooves 201 correspond to the plurality of windows 301, respectively.

The plurality of grooves 201 are spaced apart, with a protrusion 202 formed between two adjacent the grooves 201. A depth of the groove 201 may be less than a thickness of the second semiconductor layer 2. The groove 201 may have a strip-shaped section, and the plurality of grooves 201 all extend in a first direction (herein, the first direction is a thickness direction of the second semiconductor layer 2), that is, the plurality of grooves 201 extend in the same direction. At least two of the plurality of grooves 201 are spaced apart along the second direction, which is perpendicular to the first direction. At least two of the plurality of grooves 201 have different depths in the first direction. The present disclosure can avoid the problem of grinding process (for example, CMP process) easily causing the protrusions 202 to be grinded off in the related art, and it is not easy to generate cracks caused by stress accompanied by temperature changes in the present disclosure. In addition, the present disclosure can also reduce the difference in etching rates between the mask layer 3 and the second semiconductor layer 2 by adjusting conditions such as gas type, pressure, radio frequency (RF) power, etc.

In step S140, the third semiconductor layer 4 is epitaxially grown. The third semiconductor layer 4 is of a different conductive type than the second semiconductor layer 2. The third semiconductor layer 4 is of a different material than the second semiconductor layer 2. At least a portion of the third semiconductor layer 4 is disposed in the grooves 201.

The material of this third semiconductor layer 4 may be a III-V group compound. Specifically, the material of the third semiconductor layer 4 may be at least one of GaN, AlGaN, InGaN, or AlInGaN. The third semiconductor layer 4 has a different conductive type than the first semiconductor layer 1. When the first semiconductor layer 1 is an N-type semiconductor layer, the third semiconductor layer 4 is a P-type semiconductor layer. When the first semiconductor layer 1 is a P-type semiconductor layer, the third semiconductor layer 4 is an N-type semiconductor layer. In addition, as shown in FIG. 4, the horizontal projection of the third semiconductor layer 4 may be hexagonal and distributed in a hexagonal shape.

Specifically, the materials of the first semiconductor layer 1 and the second semiconductor layer 2 are at least one of Si, SiC, or GaN, and the third semiconductor layer 4 is AlGaN; or the materials of the first semiconductor layer 1 and the second semiconductor layer 2 are at least one of Si, SiC, or GaN, and the third semiconductor layer 4 is SiC.

When the material of the second semiconductor layer 2 is GaN and the material of the third semiconductor layer 4 is AlGaN, a change curve of an Al component transitions continuously at the contact interface between the third semiconductor layer 4 and the second semiconductor layer 2. When the material of the second semiconductor layer 2 is SiC and the material of the third semiconductor layer 4 is AlGaN, the change curve of the Al component has a jump at the contact interface between the third semiconductor layer 4 and the second semiconductor layer 2, because the third semiconductor layer 4 at the interface has a high Al component, preventing the diffusion of doping ions from the second semiconductor layer 2 to the third semiconductor layer 4.

The semiconductor structure in the embodiment I of the present disclosure may include: a first semiconductor layer 1, including a first surfaces and a second surfaces opposite to the first surface; a second semiconductor layer 2, disposed on the first semiconductor layer 1, where a conductive type of the second semiconductor layer 2 is the same as that of the first semiconductor layer 1, and a doping concentration of the second semiconductor layer 2 is less than that of the first semiconductor layer 1; grooves 201, formed in the second semiconductor layer 2; and a third semiconductor layer 4, where a conductive type of the third semiconductor layer 4 is different from that of the second semiconductor layer 2, a material of the third semiconductor layer 4 is different from that of the second semiconductor layer 2, and at least a portion of the third semiconductor layer 4 is disposed in the grooves 201.

The method for manufacturing the semiconductor structure provided in the embodiments of the present disclosure and the semiconductor structure belong to the same inventive concept, and the relevant details and descriptions of the beneficial effects can be found in each other and will not be repeated.

### Embodiment II

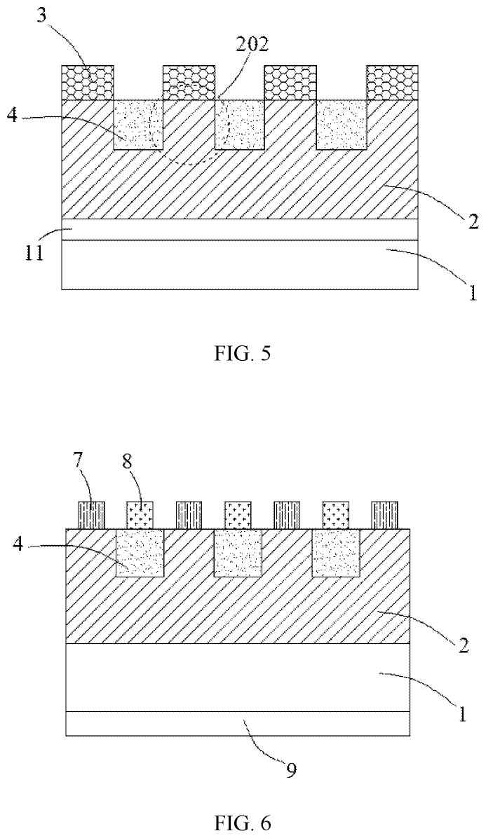

FIG. 5 is a schematic diagram illustrating a semiconductor structure manufactured according to the embodiment II of the present disclosure. The method of the embodiment II is substantially the same as the method of embodiment I, with the difference that in step S110, a buffer layer 11 covering the first semiconductor layer 1 is formed before the second semiconductor layer 2 is formed, and the second semiconductor layer 2 is formed on a side of the buffer layer 11 away from the first semiconductor layer 1.

The buffer layer 11 has the same conductive type as the conductive type of the first semiconductor layer 1. For example, the buffer layer 11 is an N-type buffer layer 11. The buffer layer 11 may be a single-layer structure or a stacked-layer structure, and the material of each layer may be GaN, AlGaN, or AlInGaN, or other semiconductor materials including Ga atoms, N atoms, or at least two of the above-mentioned materials or mixtures thereof. The buffer layer 11 may be formed by epitaxial growth, but the embodiments of the present disclosure are not specifically limited thereto.

### Embodiment III

FIG. 6 is a schematic diagram illustrating a semiconductor structure manufactured according to an embodiment IR of the present disclosure. The method of the embodiment III is substantially the same as the method of the embodiment I or II, with the difference that the method of the embodiment III further includes: removing the mask layer 3; forming a gate electrode 8 on a side of the third semiconductor layer 4 away from the first semiconductor layer 1; forming a source electrode 7 on a top surface of the protrusion 202; and forming a drain electrode 9 on a side of the first semiconductor layer 1 away from the second semiconductor layer 2. The semiconductor structure of the present disclosure is applied to a junction-type field effect tube, the third semiconductor layer 4 in the grooves 201 can automatically expand the depletion region on both sides under a large surge voltage, control the electric field distribution of the second semiconductor layer 2 between the source electrode 7 and the drain electrode 9, and prevent an avalanche breakdown at the gate electrode 8, to improve the actual breakdown voltage of the device, and enhance the reliability of the device.

The third semiconductor layer 4 in the grooves 201 is formed by epitaxial growth with the P-type AlGaN material. When the semiconductor structure is applied to a junction field effect tube, since the third semiconductor layer 4 adopts the P-type AlGaN material and the second semiconductor layer 2 adopts any one of Si, SiC, and GaN, the third semiconductor layer 4 has the ability to be self-polarized. Since the third semiconductor layer 4 is of a different material from the second semiconductor layer 2, the third semiconductor layer 4 forms a PN junction by heteroepitaxial growth on the second semiconductor layer 2. Compared to homogeneous epitaxy, the third semiconductor layer 4 has a greater range of control over the aggregation and depletion of electrons, the breakdown voltage is effectively increased, the thickness of the depletion layer is increased, and the on-resistance is reduced.

The second semiconductor layer 2 is etched to form the grooves 201, and the third semiconductor layer 4 is formed by secondary epitaxy in the grooves 201. By means of epitaxial growth, it can be ensured that the shape of the PN junction interface between the second semiconductor layer 2 and the third semiconductor layer 4 and the sidewalls of the grooves 201 have approximately the same shape, which is convenient for controlling the shape of the third semiconductor layer 4, thereby the electric field exerted by the drain electrode 9 is effectively relieved, and the breakdown voltage is increased. On the other hand, the third semiconductor layer 4 is formed by epitaxial growth and has fewer crystal defects, which helps reduce the open-state resistance of the semiconductor structure.

When the device is disconnected, a reverse voltage is applied to the PN junction at the interface, i.e., the second semiconductor layer 2 becomes a higher potential voltage compared to the third semiconductor layer 4. Thus, the depletion layer extends from the third semiconductor layer 4 to the second semiconductor layer 2, depletion of the second semiconductor layer 2 occurs, and potential distribution occurs in the second semiconductor layer 2.

### Embodiment IV

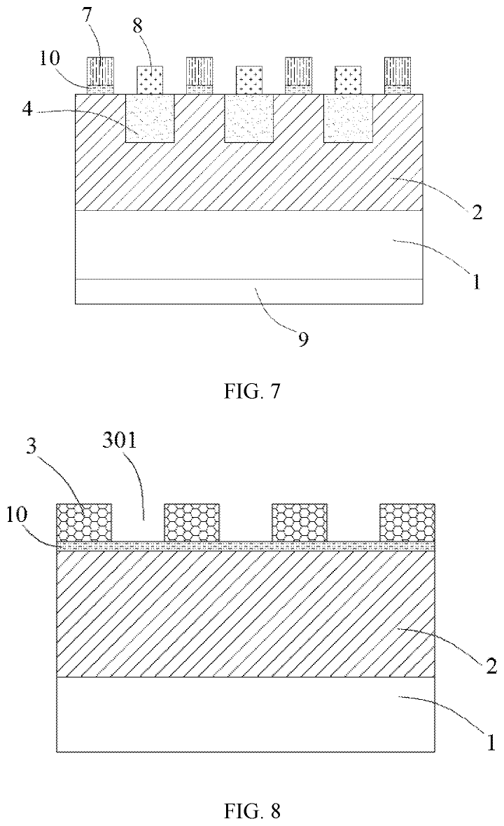

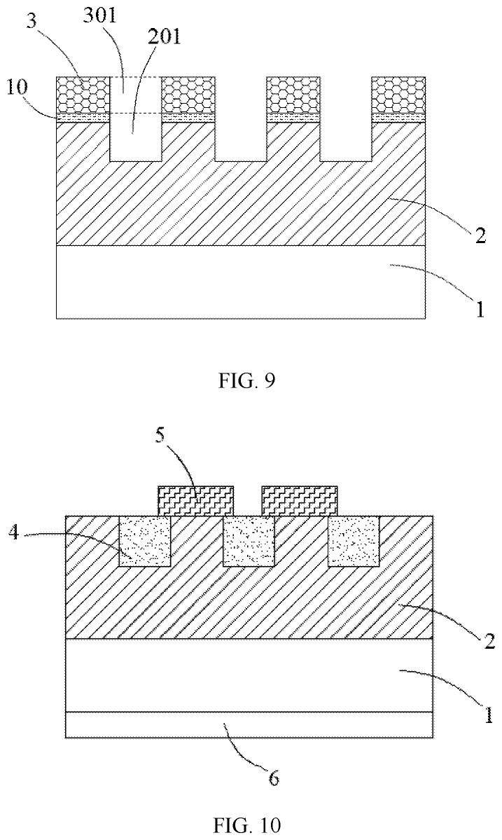

FIG. 7 is a schematic diagram illustrating a semiconductor structure manufactured according to the embodiment IV of the present disclosure. FIG. 8 is a schematic diagram illustrating a structure after forming a mask layer according to the embodiment IV of the present disclosure. FIG. 9 is a schematic diagram illustrating a structure after forming grooves according to the embodiment IV of the present disclosure. The method of the embodiment IV is substantially the same as the method of the embodiment IQ, with the difference that, before forming the source electrode 7, the method of the embodiment IV further includes: forming a fourth semiconductor structure 10 on the second semiconductor layer 2. The fourth semiconductor structure 10 is of the same conductive type as the first semiconductor layer 1, and is of an different conductive type from the third semiconductor layer 4. In contrast, the fourth semiconductor structure 10 has a doping concentration greater than the doping concentration of the second semiconductor layer 2. For example, this fourth semiconductor structure 10 is an N-type heavily doped structure which is formed on the top surface of the protrusion 202, and the source electrode 7 is formed on the side of the N-type heavily doped structure away from the projection 202. By providing the N-type heavily doped structure, the ohmic contact resistance can be reduced.

As shown in FIG. 7, the present disclosure may selectively grow the fourth semiconductor structure 10 on the second semiconductor layer 2 which is etched. In some embodiments, as shown in FIGS. 8 and 9, the present disclosure may also form the fourth semiconductor structure 10 on the second semiconductor layer 2 and form a mask layer 3 on a surface of the fourth semiconductor structure 10 away from the second semiconductor layer 2, and the grooves 201 penetrate the fourth semiconductor structure 10 and extend into the second semiconductor layer 2.

### Embodiment V

FIG. 10 is a schematic diagram illustrating a semiconductor structure manufactured according to the embodiment V of the present disclosure. The method of the embodiment V is substantially the same as the method of the embodiment I or II, with the difference that the method of the embodiment V further includes: removing the mask layer 3; forming a first electrode 5, where the first electrode 5 is in contact with the third semiconductor layer 4 and in contact with the second semiconductor layer 2 disposed between two adjacent grooves 201; and forming a second electrode 6 on a side of the first semiconductor layer 1 away from the second semiconductor layer 2. The first electrode 5 may be a full-face electrode covering the third semiconductor layer 4 and the second semiconductor layer 2, or a plurality of electrodes separated from each other. The first semiconductor layer 1 may be of the same material as the second semiconductor layer 2. When the semiconductor structure of the present invention is applied to a Schottky barrier diode, the third semiconductor layer 4 in the grooves 201 can automatically expand automatically expand the depletion region on both sides under a large surge voltage, control the electric field distribution of the second semiconductor layer 2 between the first electrode 5 and the second electrode 6, and prevent an avalanche breakdown, to improve the actual breakdown voltage of the Schottky barrier diode, and enhance the reliability of the device. Since the third semiconductor layer 4 adopts the P-type AlGaN material and the second semiconductor layer 2 adopts any one of Si, SiC, and GaN, the third semiconductor layer 4 has the ability to be self-polarized. Since the third semiconductor layer 4 is of a different material from the second semiconductor layer 2, the third semiconductor layer 4 forms a PN junction by heteroepitaxial growth on the second semiconductor layer 2. Compared to homogeneous epitaxy, the third semiconductor layer 4 has a greater range of control over the aggregation and depletion of electrons, the breakdown voltage is effectively increased, the thickness of the depletion layer is increased, and the on-resistance is reduced.

### Embodiment VI

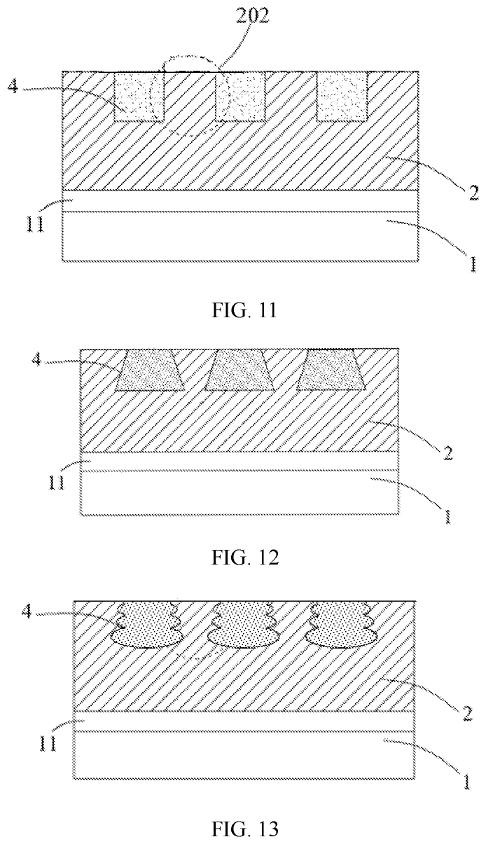

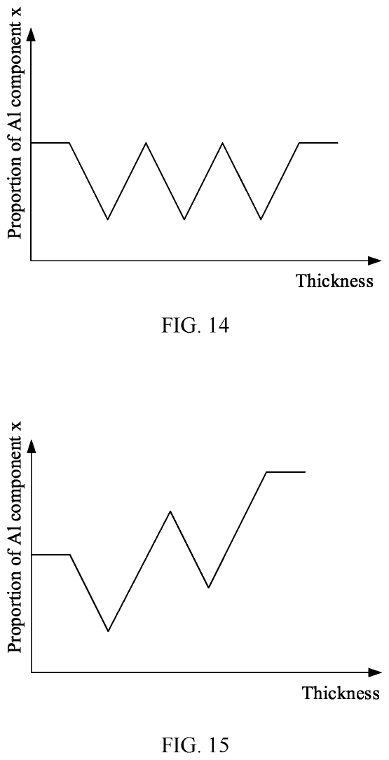

FIGS. 11 to 13 are schematic diagrams illustrating a semiconductor structure manufactured according to the embodiment VI of the present disclosure. FIGS. 14 to 16 are graphs illustrating changes of an Al component in a third semiconductor layer. The method of the embodiment VI is substantially the same as the method of the embodiment I or II, with the difference that the method of the embodiment VI further includes: removing the mask layer 3, as shown in FIG. 11. In addition, as shown in FIG. 12, the width of the third semiconductor layer 4 is progressively decreases along a epitaxial direction (herein, the epitaxial direction is a direction in which the third semiconductor layer 4 is epitaxially grown). As shown in FIG. 13, the width of the third semiconductor layer 4 may first increase and then decrease, or first decrease and then increase along the epitaxial direction, but the present disclosure is not limited to thereto, and the width of this third semiconductor layer 4 may gradually increase along the epitaxial direction. Since the width of the third semiconductor layer 4 varies periodically (increasing or decreasing), the contact interface between the third semiconductor layer 4 and the side of the second semiconductor layer 2 undergoes periodic changes or forms a inclined surface. By controlling the shape of the PN junction contact interface, the breakdown voltage is effectively alleviated and the reverse breakdown voltage is increased. On the other hand, in the open state, due to the periodic changes in the surface or inclined surface of the contact interface, electrons flowing from the source to the drain can disperse on both sides and flow downwards, such that the electron movement path is increased, and the open state resistance of the semiconductor structure is further reduced.

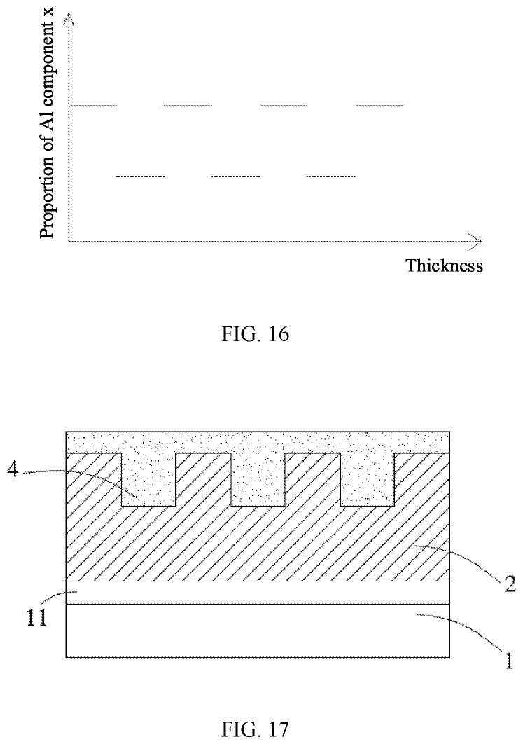

In the embodiment of the present invention, the third semiconductor layer 4 includes at least one component changing element that changes in the epitaxial direction. As shown in FIGS. 14-16, the change curve of the element content in the epitaxial direction includes one or more combinations of the following change stages: periodic change, incremental change, and decreasing change. The change curve shown in FIG. 14 includes periodic changes, incremental changes, and decreasing changes. The change curve shown in FIG. 15 includes increasing and decreasing changes. The change curve shown in FIG. 16 includes periodic changes. For example, the third semiconductor layer 4 is AlGaN, the component changing element is Al element. The present disclosure locally modulates the carrier concentration in the second semiconductor layer 2 by controlling the Al component change of the third semiconductor layer 4. After the device is optimized, the effect of locally modulated carrier concentration is that: in the off state, the carrier concentration of the Al component in the third semiconductor layer 4 can increase the width of the depletion layer, reduce the peak electric field, and thus increase the breakdown voltage; in the open state, the structure has the characteristic of reducing the conduction resistance, such that the semiconductor structure has a lower voltage drop under high current density conditions when turned on. Thus, the energy conversion efficiency of the system using the device is improved.

### Embodiment VII

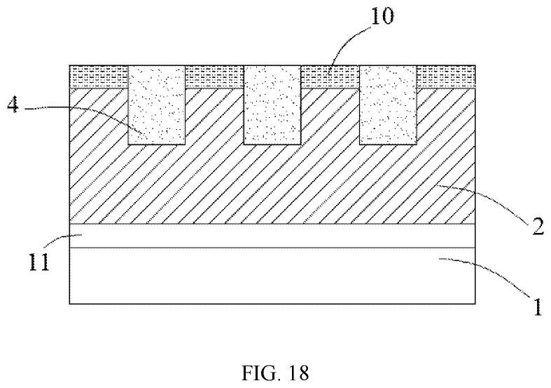

FIGS. 17 and 18 are schematic diagrams illustrating the semiconductor structures according to the embodiment VII of the present disclosure. The semiconductor structure of the embodiment VII is substantially the same as the semiconductor structure of the embodiment I or II, with the difference that: the third semiconductor layer 4 extends outside the grooves 201 and heals into a flat surface, and the third semiconductor layer 4 outside the groove 201 is injected with high-dose N-type ions to form an N-type heavily doped fourth semiconductor structure 10, thereby the conduction resistance of the semiconductor structure is reduced.

The above descriptions are made only to the preferred embodiments of the present disclosure and not intended to limit the present disclose in any form. Although the present disclosure is already described with the preferred embodiments as above, the preferred embodiments are not meant to limit the present disclosure. Those skilled in the art can, without departing from the scope of the technical solutions of the present disclosure, make some changes to the above-disclosed technical contents or modify them as equivalent embodiments of equivalent changes. But, any simple changes, equivalent changes and modifications made to the above embodiments based on the technical essence of the present disclosure without departing from the contents of the technical solutions of the present disclosure shall fall within the scope of the technical solutions of the present disclosure.

What is claimed is:

1. A semiconductor structure, comprising:
a first semiconductor layer, comprising a first surfaces and a second surfaces opposite to the first surface;
a second semiconductor layer, disposed on the first semiconductor layer, wherein a conductive type of the second semiconductor layer is the same as that of the first semiconductor layer, and a doping concentration of the second semiconductor layer is less than that of the first semiconductor layer;
grooves, formed in the second semiconductor layer; and
a third semiconductor layer, wherein a conductive type of the third semiconductor layer is different from that of the second semiconductor layer, a material of the third semiconductor layer is different from that of the second semiconductor layer, and at least a portion of the third semiconductor layer is disposed in the grooves.

2. The semiconductor structure of claim 1, wherein a width of the third semiconductor layer periodically varies, gradually increases, gradually decreases, first increases and then decreases or first decreases and then increases along an epitaxial direction.

3. The semiconductor structure of claim 1, wherein the conductive type of the first semiconductor layer is an N-type, and the conductive type of the third semiconductor layer is a P-type; or the conductive type of the first semiconductor layer is a P-type, and the conductive type of the third semiconductor layer is a N-type.

4. The semiconductor structure of claim 1, further comprising a buffer layer, which is provided between the first semiconductor layer and the second semiconductor layer.

5. The semiconductor structure of claim 1, wherein
a material of the first semiconductor layer and the material of the second semiconductor layer comprise at least one of Si, SiC or GaN, and the material of the third semiconductor layer comprises AlGaN; or
a material of the first semiconductor layer and the material of the second semiconductor layer comprise at least one of Si, SiC or GaN, and the material of the third semiconductor layer comprises SiC.

6. The semiconductor structure of claim 5, wherein
when the material of the second semiconductor layer is GaN and the material of the third semiconductor layer is AlGaN, a change curve of an Al component transitions continuously at a contact interface between the third semiconductor layer and the second semiconductor layer;
when the material of the second semiconductor layer is SiC and the material of the third semiconductor layer is AlGaN, the change curve of the Al component has a jump at the contact interface between the third semiconductor layer and the second semiconductor layer.

7. The semiconductor structure of claim 5, wherein in the epitaxial direction, a change curve of an Al component of the third semiconductor layer comprises one or more combinations of a periodic change, an incremental change and a decremental change.

8. The semiconductor structure of claim 1, further comprising a fourth semiconductor structure formed on the second semiconductor layer, wherein a conductive type of the fourth semiconductor structure is the same as that of the second semiconductor layer, a doping concentration of the fourth semiconductor structure is greater than that of the second semiconductor layer, and the grooves penetrate the fourth semiconductor structure and extend into the second semiconductor layer.

9. The semiconductor structure of claim 8, wherein the third semiconductor layer extends outside the grooves and heals into a flat surface, and the third semiconductor layer outside the grooves is ion-implanted to form the fourth semiconductor structure.

10. The semiconductor structure of claim 1, further comprising a source electrode, a gate electrode, and a drain electrode, wherein the source electrode is disposed on the second semiconductor layer, the gate electrode is disposed on a top surface of the third semiconductor layer, and the drain electrode is disposed on the second surface of the first semiconductor layer.

11. The semiconductor structure of claim 1, further comprising:
a first electrode, disposed on a top surface of the third semiconductor layer; and
a second electrode, disposed on the second surface of the first semiconductor layer.

12. A method for manufacturing a semiconductor structure, comprising:
providing a first semiconductor layer;
forming a second semiconductor layer on the first semiconductor layer, wherein a conductive type of the second semiconductor layer is the same as that of the first semiconductor layer, and a doping concentration of the second semiconductor layer is less than that of the first semiconductor layer;
forming a mask layer on a surface of the second semiconductor layer away from the first semiconductor layer, wherein the mask layer is provided with windows exposing the second semiconductor layer;
etching the second semiconductor layer by using the mask layer as a mask to form grooves in the second semiconductor layer, wherein the grooves correspond to the windows; and
epitaxially growing a third semiconductor layer, wherein a conductive type of the third semiconductor layer is different from that of the second semiconductor layer, a material of the third semiconductor layer is different from that of the second semiconductor layer, and at least a portion of the third semiconductor layer is disposed in the grooves.

13. The method of claim 12, wherein a width of the third semiconductor layer periodically varies, gradually increases, gradually decreases, first increases and then decreases or first decreases and then increases along an epitaxial direction.

14. The method of claim 12, wherein
a material of the first semiconductor layer and the material of the second semiconductor layer comprise at least one of Si, SiC or GaN, and the material of the third semiconductor layer comprises AlGaN; or
a material of the first semiconductor layer and the material of the second semiconductor layer comprise at least one of Si, SiC or GaN, and the material of the third semiconductor layer comprises SiC.

15. The method of claim 14, wherein
when the material of the second semiconductor layer is GaN and the material of the third semiconductor layer is AlGaN, a change curve of an Al component transitions continuously at a contact interface between the third semiconductor layer and the second semiconductor layer;
when the material of the second semiconductor layer is SiC and the material of the third semiconductor layer is AlGaN, the change curve of the Al component has a jump at the contact interface between the third semiconductor layer and the second semiconductor layer.

16. The method of claim 14, wherein in the epitaxial direction, a change curve of an Al component of the third semiconductor layer comprises one or more combinations of a periodic change, an incremental change and a decremental change.

17. The method of claim 12, further comprising:
selectively growing a fourth semiconductor structure on the second semiconductor layer which is etched; or
before forming the mask layer: forming a fourth semiconductor structure on the second semiconductor layer, wherein the mask layer is formed on a surface of the fourth semiconductor structure away from the second semiconductor layer, and the grooves penetrate the fourth semiconductor structure and extend into the second semiconductor layer; or
growing the third semiconductor layer to extend outside the recess and heal into a flat surface, wherein the third semiconductor layer outside the grooves is ion-implanted to form the fourth semiconductor structure;
wherein a conductive type of the fourth semiconductor structure is the same as that of the second semiconductor layer, a doping concentration of the fourth semiconductor structure is greater than that of the second semiconductor layer.

18. The method of claim 12, further comprising:
removing the mask layer;
forming a first electrode, wherein the first electrode is in contact with the third semiconductor layer and in contact with the second semiconductor layer disposed between two adjacent grooves; and
forming a second electrode on a side of the first semiconductor layer away from the second semiconductor layer.

19. The method of claim 12, wherein a protrusion is formed between two adjacent grooves, and the method further comprises:
removing the mask layer;
forming a gate electrode on a side of the third semiconductor layer away from the first semiconductor layer;
forming a source electrode on a top surface of the protrusion; and
forming a drain electrode on a side of the first semiconductor layer away from the second semiconductor layer.

20. The method of claim 12, wherein forming the second semiconductor layer on the first semiconductor layer comprises:
forming a buffer layer covering the first semiconductor layer, and
forming the second semiconductor layer on a side of the buffer layer away from the first semiconductor layer.
